(19) United States
(12) Patent Application Publication
(10) Pub. No.: US 2007/0134830 A1
(43) Pub. Date: Jun. 14, 2007

(54) Drive film, drive package for organic light emitting diode display, method of manufacturing thereof, and organic light emitting diode display including the same

(76) Inventors: Kyong-Tae Park, Suwon-si (KR); Chun-Seok Ko, Hwaseong-si (KR); Si-Duk Sung, Seoul (KR)

Correspondence Address: CANTOR COLBURN, LLP, 55 GRIFFIN ROAD SOUTH, BLOOMFIELD, CT, 06002, US

(21) Appl. No.: 11/455,307

(22) Filed: Jun. 16, 2006

(30) Foreign Application Priority Data
Dec. 8, 2005 (KR) 10-2005-0074340

(51) Int. Cl. H01L 21/00

(52) U.S. Cl. 438/26

(57) ABSTRACT

The present description relates to a drive film, a drive package for an organic light emitting diode display, a method of manufacturing thereof, and an organic light emitting diode display including the same. A drive package for an organic light emitting diode display includes a base film including a central region and a peripheral region, a drive circuit chip mounted on the central region of the base film, a plurality of conductors formed on at least one portion of the peripheral region of the base film, and at least one protective film formed on the conductors and exposing both ends of the conductors in a lengthwise direction.

This application claims priority to Korean Patent Application No. 10-2005-0074340, filed on Aug. 12, 2005 and all the benefits accruing therefrom under 35 U.S.C. §119, and the contents of which in its entirety are herein incorporated by reference.

### BACKGROUND OF THE INVENTION

(a) Field of the Invention

The present invention relates to a drive film, a drive package for an organic light emitting diode (“OLED”) display, a method of manufacturing thereof, and an OLED display including the same. More particularly, the present invention relates to a drive film, a drive package for providing increased current to an OLED display, a method of manufacturing to simplify the manufacture of an OLED display, and an OLED display including the same.

(b) Description of the Related Art

Recent trends of light-weight and thin personal computers and televisions sets require light-weight and thin display devices, and flat panel displays satisfying such a requirement are being substituted for conventional cathode ray tubes (“CRTs”).

Flat panel displays include a liquid crystal display (“LCD”), a field emission display (“FED”), an organic light emitting diode (“OLED”) display, a plasma display panel (“PDP”), and so on.

Generally, an active matrix flat panel display includes a plurality of pixels arranged in a matrix, and it displays images by controlling the luminance of the pixels based on given luminance information. An OLED display is a self-emissive display device, and thus does not require an exterior light source. The OLED display displays images by electrically exciting light emitting organic material, and it has low power consumption, a wide viewing angle, and a fast response time, thereby being advantageous for displaying motion images.

A pixel of an OLED display includes an OLED and a thin film transistor (“TFT”) for driving the same. The driving transistor is either a poly silicon TFT or an amorphous silicon TFT according to the material of an active layer.

### BRIEF SUMMARY OF THE INVENTION

The present invention provides a drive film, a drive package for an organic light emitting diode display, a method of manufacturing thereof, and an organic light emitting diode display including the same having advantages of supplying much more current for effectively using limited areas and providing an OLED display that can be manufactured more simply with low cost.

Exemplary embodiments of the present invention provide a drive package for an organic light emitting diode (“OLED”) display, including a base film with a central region and a peripheral region, a drive circuit chip mounted on the central region of the base film, a plurality of conductors formed on at least one portion of the peripheral region of the base film, and at least one protective film formed on the conductors and exposing both ends of the conductors in a lengthwise direction.

The conductors may include one pair of conductors formed to face each other on opposing sides of the base film, where the drive circuit chip is disposed between the conductors in the pair of conductors.

The conductors may include a first pair of conductors formed on a first side of the base film and a second pair of conductors formed on a second side of the base film, a first gap may be disposed between the first pair of conductors and a second gap may be disposed between the second pair of conductors.

Each of the plurality of conductors may be a thin flat strip extending from an input terminal to an output terminal of the drive package, and each of the plurality of conductors may have a width greater than a thickness thereof. Each of the plurality of conductors may be substantially rectangular-shaped.

The base film may include a first base film supporting the drive circuit chip and a second base film supporting at least one of the plurality of conductors, the first base film connected to the second base film. The base film may further include a third base film supporting at least one of the plurality of conductors, the third base film connected to the first base film.

The drive package may further include metal wiring extending from an input terminal to the drive circuit chip and from the drive circuit chip to an output terminal, and a cross-sectional area of each of the conductors may be substantially greater than a cross-sectional area of each wire in the metal wiring.

Other exemplary embodiments of the present invention provide an OLED display including a substrate, a display region formed on the substrate, and a plurality of first drive packages successively attached to an upper or lower peripheral region of the substrate except for the display region of the substrate. Each of the first drive packages includes a base film having a central region and a peripheral region, a first drive circuit chip mounted on the central region of the base film, a plurality of conductors formed on at least one portion of the peripheral region of the base film, and at least one protective film formed on the conductors and exposing both ends of the conductors in a lengthwise direction.

Here, the conductors may include one pair of conductors formed to face each other on both sides of the base film, and the first drive circuit chip may be disposed between the conductors in the pair of conductors.

The conductors may include a first pair of conductors formed on a first side of the base film and a second pair of conductors formed on a second side of the base film. A gap may be disposed between the conductors in each pair of conductors.

The conductors may transfer a common voltage or a drive voltage.

The drive circuit chip may include a data drive integrated circuit.

The OLED display may further include a plurality of second drive packages successively attached to left or right peripheral regions of the substrate outside of the display region of the substrate. Each of the second drive packages contains a base film including a central region and a peripheral region, a drive circuit chip mounted on the central region of the base film, conductors formed on at least one portion of the peripheral region of the base film, and at least one protective film formed on the conductors and exposing both ends of the conductors in a lengthwise direction.

The conductors of the second drive packages may transfer a common voltage.

The drive circuit chip of the second drive packages may include a scanning drive integrated circuit.

The conductors of the second drive packages may include one pair of conductors formed to face each other on opposing sides of the base film.

Other exemplary embodiments of the present invention provide a manufacturing method of a drive package for an OLED display, including forming metal wiring on a first base film, mounting a drive circuit chip connected to the metal wiring on the first base film, forming at least one conductor on a second base film, forming at least one protective film on the at least one conductor where the protective film exposes both ends in a lengthwise direction of the at least one conductor, and attaching the first base film and the second base film to each other.

The at least one conductor may include one pair of conductors separated from each other.

Forming at least one conductor on the second base film may include forming each of the at least one conductor in a shape of a thin flat strip from an input terminal to an output terminal of the drive package, and having a width substantially greater than a thickness thereof.

Forming at least one conductor on the second base film may include forming each of the at least one conductor with a cross-sectional area substantially greater than a cross-sectional area of each wire in the metal wiring.

The method may further include forming at least one conductor on a third base film, forming at least one protective film on the at least one conductor on the third base film where the at least one protective film on the third base film exposes both ends in a lengthwise direction of the conductors on the third base film, and attaching the third base film and the first base film to each other.

The at least one conductor on the third base film may include one pair of conductors that are separated from each other.

Other exemplary embodiments of the present invention provide a drive film including a first base film having a hole in a central region, the hole sized to receive a drive circuit chip, the first base film having a first edge corresponding to an input terminal of the drive package, a second edge corresponding to an output terminal of the drive package, the second edge opposite the first edge, a third edge, and a fourth edge opposite the third edge, and a second base film attached to the third edge of the first base film during manufacture of the drive package.

The drive film may further include a third base film, wherein the third base film is attached to the fourth edge of the first base film during manufacture of the drive package.

### BRIEF DESCRIPTION OF THE DRAWINGS

The above and other features and advantages of the present invention will become more apparent by describing exemplary embodiments thereof with reference to the accompanying drawings, in which:

FIG. 1 is a block diagram of an exemplary OLED display according to an exemplary embodiment of the present invention;

FIG. 2 is an equivalent circuit diagram of an exemplary pixel of an exemplary OLED display according to an exemplary embodiment of the present invention;

FIG. 3 is an exemplary sectional view of an exemplary OLED and an exemplary driving transistor of an exemplary pixel of an exemplary OLED display shown in FIG. 2;

FIG. 4 is a schematic diagram of an exemplary OLED of an exemplary OLED display according to an exemplary embodiment of the present invention;

FIG. 5 is a plan view of an exemplary OLED display according to an exemplary embodiment of the present invention;

FIG. 6 is a plan view of an exemplary OLED display according to another exemplary embodiment of the present invention;

FIG. 7 is a plan view of an exemplary drive package according to an exemplary embodiment of the present invention;

FIG. 8 is a sectional view of the exemplary drive package shown in FIG. 7 taken along line VIII-VIII;

FIG. 9 is a sectional view of the exemplary drive package shown in FIG. 7 taken along line IX-IX;

FIG. 10 is a sectional view of the exemplary drive package shown in FIG. 7 taken along line X-X;

FIG. 11 is a sectional view of an exemplary drive package according to another exemplary embodiment of the present invention;

FIG. 12 is a plan view of an exemplary drive package according to another exemplary embodiment of the present invention;

FIG. 13 is a plan view of an exemplary OLED display according to another exemplary embodiment of the present invention; and,

FIG. 14 is a plan view of an exemplary drive package according to another exemplary embodiment of the present invention.

### DETAILED DESCRIPTION OF THE INVENTION

With reference to the accompanying drawings, the present invention will be described in order for those skilled in the art to be able to implement the invention. As those skilled in the art would realize, the described embodiments may be modified in various different ways, all without departing from the spirit or scope of the present invention.

To clarify multiple layers and regions, the thicknesses of the layers are enlarged in the drawings. Like reference numerals designate like elements throughout the specification. When it is said that any part, such as a layer, film, area, or plate is positioned on another part, it means the part is directly on the other part or above the other part with at least one intermediate part. On the other hand, if any part is said to be positioned directly on another part it means that there is no intermediate part between the two parts. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In general, the larger an OLED display becomes, the more current is needed to display the same luminance, so current intensity that can be supplied is an important factor in determining uniformity of a display. However, supplying a large amount of current using an edge area of a limited width is not easy with a large display panel.

Therefore, as will be described below with reference to the exemplary embodiments, the present invention supplies much more current to effectively use limited areas and to provide an OLED display that can be manufactured more simply with a low cost.

Now, exemplary drive films, drive packages for OLED displays, methods of manufacturing thereof, and OLED display devices including the same according to exemplary embodiments of the present invention will be described with reference to the accompanying drawings.

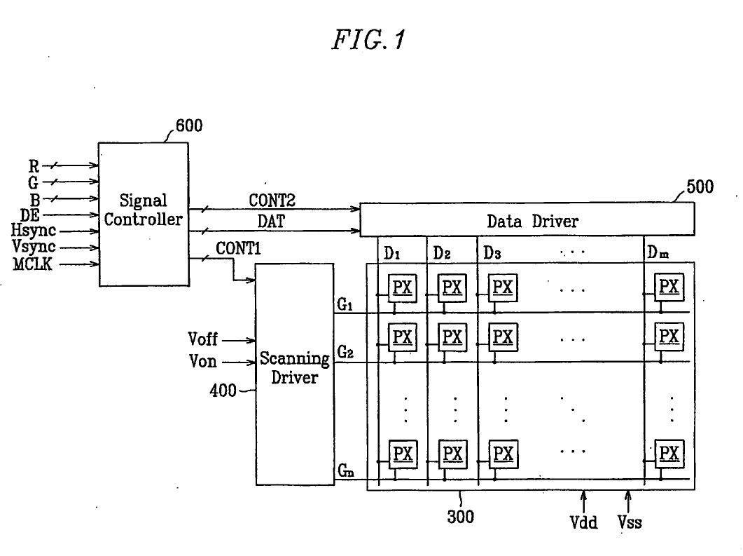

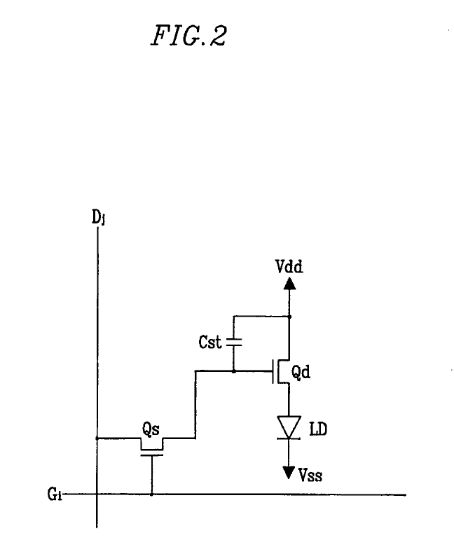

FIG. 1 is a block diagram of an exemplary OLED display according to an exemplary embodiment of the present invention, and FIG. 2 is an equivalent circuit diagram of an exemplary pixel of an exemplary OLED display according to an exemplary embodiment of the present invention.

As shown in FIG. 1, an OLED display includes a display panel 300, a scanning driver 400 and a data driver 500 that are connected to the display panel 300, and a signal controller 600 for controlling the scanning driver 400 and the data driver 500.

The display panel 300 includes a plurality of display signal lines G₁-Gₙ and D₁-Dₘ, a plurality of drive voltage lines (not shown), and a plurality of pixels PX connected to the above elements and arranged substantially in a matrix, as illustrated.

The display signal lines G₁-Gₙ and D₁-Dₘ include a plurality of scanning lines G₁-Gₙ, also known as gate lines, for transmitting scanning signals, also known as gate signals, and a plurality of data lines D₁-Dₘ, also known as source lines, for transmitting data voltages, also known as source signals.

The scanning lines G₁-Gₙ extend substantially in a row direction, a first direction, and are separated from and substantially parallel to each other.

The data lines D₁-Dₘ extend substantially in a column direction, a second direction, and are separated from and substantially parallel to each other. The first direction is substantially perpendicular to the second direction.

The drive voltage lines transmit a drive voltage Vdd to each of the pixels PX.

As shown in FIG. 2, each pixel PX, for example, the pixel connected to the scanning line Gᵢ and the data line Dⱼ, includes an OLED LD, a driving transistor Qd, a capacitor Cst, and a switching transistor Qs.

The driving transistor Qd is a three-terminal element and has a control terminal, such as a gate electrode, connected to the switching transistor Qs and the capacitor Cst, an input terminal, such as a source electrode, connected to a drive voltage Vdd, and an output terminal, such as a drain electrode, connected to the OLED LD.

The switching transistor Qs is also a three-terminal element and has a control terminal, such as a gate electrode, connected to the scanning line Gᵢ, an input terminal, such as a source electrode, connected to the data line Dⱼ, and an output terminal, such as a drain electrode, connected to the capacitor Cst and the driving transistor Qd.

The capacitor Cst is connected between the switching transistor Qs and a drive voltage Vdd, such as between the output terminal of the switching transistor Qs and the drive voltage Vdd. The capacitor Cst is also connected between the control terminal of the driving transistor Qd and the drive voltage Vdd. The capacitor Cst stores and preserves the data voltage applied from the switching transistor Qs for a predetermined time.

The OLED LD has an anode connected to the driving transistor Qd and a cathode connected to the common voltage Vss. The OLED LD displays images by emitting light having intensity depending on the current I_{LD} supplied from the output terminal of the driving transistor Qd. The current I_{LD} supplied from the driving transistor Qd depends on the voltage Vgs between the control terminal and the output terminal of the driving transistor Qd.

The switching transistor Qs and the driving transistor Qd are n-channel field effect transistors (“FETs”) including amorphous silicon (“a-Si”) or polysilicon. However, the transistors Qs and Qd may be p-channel FETs, and in this case, since the p-channel FETs and the n-channel FETs are complementary to each other, the operations, voltages, and currents of the p-channel FETs are opposite to those of the n-channel FETs.

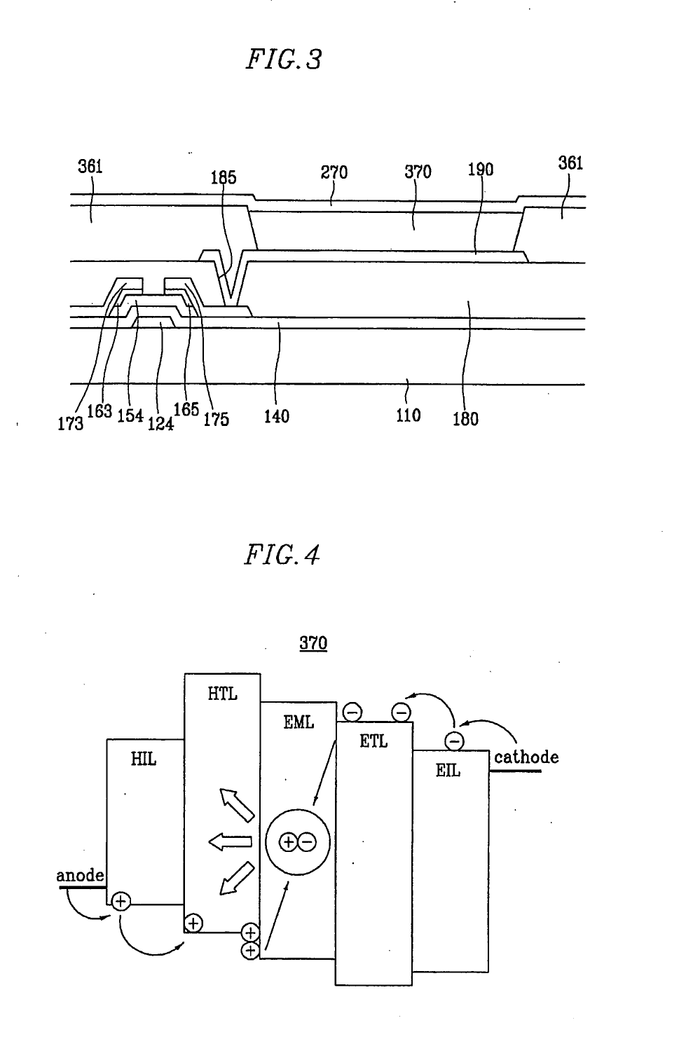

Now, a structure of an OLED LD and a driving transistor Qd of the OLED display illustrated in FIG. 2 will be further described with reference to FIG. 3 and FIG. 4.

FIG. 3 is an exemplary sectional view of an exemplary OLED and an exemplary driving transistor of an exemplary pixel of an exemplary OLED display shown in FIG. 2, and FIG. 4 is a schematic diagram of an exemplary OLED of an exemplary OLED display according to an exemplary embodiment of the present invention.

A control electrode 124, such as a gate electrode, is formed on an insulating substrate 110. The control electrode 124 is preferably made of an aluminum Al-containing metal such as Al and an Al alloy, a sliver Ag-containing metal such as Ag and a Ag alloy, a copper Cu-containing metal such as Cu and a Cu alloy, a molybdenum Mo-containing metal such as Mo and a Mo alloy, chromium Cr, titanium Ti, and tantalum Ta. However, the control electrode 124 may have a multi-layered structure including two conductive films (not shown) having different physical characteristics. In such a multi-layered structure, one of the conductive films is preferably made of a low resistivity metal such as an Al-containing metal, a Ag-containing metal, and a Cu-containing metal for reducing signal delay or voltage drop, and another conductive film is preferably made of a material such as a Mo-containing metal, Cr, Ti, and Ta, which has good physical, chemical, and electrical contact characteristics with other materials such as indium tin oxide (“ITO”) and indium zinc oxide (“IZO”). Examples of the combination of two films in a multi-layered structure include a pair of a lower Cr film and an upper Al (alloy) film and a pair of a lower Al (alloy) film and an upper Mo (alloy) film. While particular exemplary embodiments of the control electrode 124 have been described, the control electrode 124 may be made of many various metals or conductors.

The lateral sides of the control electrode 124 are inclined relative to a surface of the substrate 110, and the preferable inclination angle thereof ranges from about 30° to about 80°.

An insulating layer 140 preferably made of, but not limited to, silicon nitride (SiNx) is formed on the control electrode 124.

A semiconductor 154 preferably made of, but not limited to, hydrogenated a-Si or polysilicon is formed on the insulating layer 140. A pair of ohmic contacts 163 and 165 preferably made of silicide or n+hydrogenated a-Si heavily doped with an n-type impurity are formed on the semiconductor 154.

The lateral sides of the semiconductor 154 and the ohmic contacts 163 and 165 are inclined relative to the surface of the substrate 110, and the preferable inclination angles thereof are in a range of about 30° to about 80°.

An input electrode 173, such as a source electrode, and an output electrode 175, such as a drain electrode, are formed on the ohmic contacts 163 and 165 and the insulating layer 140. The input electrode 173 and the output electrode 175 are preferably made of a refractory metal such as Cr, a Mo-containing metal, Ta, and Ti, and may have a multi-layered structure including a refractory metal film (not shown) and a low resistivity film (not shown) located thereon. Examples of the multi-layered structure include a double-layered structure including a lower Cr/Mo (alloy) film and an upper Al (alloy) film and a triple-layered structure including a lower Mo (alloy) film, an intermediate Al (alloy) film, and an upper Mo (alloy) film. While particular exemplary embodiments of the input electrode 173 and the output electrode 175 have been described, the input electrode 173 and the output electrode 175 may be made of many various metals or conductors.

Like the control electrode 124, the lateral sides of the input electrode 173 and the output electrode 175 are also inclined relative to a surface of the substrate 110, and the inclination angles thereof range from about 30° to about 80°.

The input electrode 173 and the output electrode 175 are separated from each other and disposed opposite each other with respect to the control electrode 124. The control electrode 124, the input electrode 173, and the output electrode 175, along with the semiconductor 154, form a driving transistor Qd having a channel formed in the semiconductor 154 between the input electrode 173 and the output electrode 175, and between the ohmic contacts 163 and 165.

The ohmic contacts 163 and 165 are interposed only between the underlying semiconductor 154 and the overlying input electrode 173 and the output electrode 175 thereon and reduce the contact resistance therebetween. The semiconductor 154 includes an exposed portion which is not covered with the input electrode 173 and the output electrode 175, thus forming the channel of the driving transistor Qd.

A passivation layer 180 is formed on the input electrode 173, the output electrode 175, the exposed portion of the semiconductor 154, and exposed portions of the insulating layer 140. The passivation layer 180 is preferably made of an inorganic insulator such as silicon nitride and silicon oxide, an organic insulator, or a low dielectric insulating material. The low dielectric material has a dielectric constant that is preferably lower than 4.0, and examples thereof are a-Si:C:O and a-Si:O:F formed by plasma enhanced chemical vapor deposition (“PECVD”). The passivation layer 180 may be made of an organic insulator having photosensitivity, and the surface of the passivation layer 180 may be flat. However, the passivation layer 180 may have a double-layered structure including a lower inorganic film and an upper organic film so that it may take the advantage of the organic film as well as protect the exposed portions of the semiconductor 154. The passivation layer 180 has a contact hole 185 exposing a portion of the output electrode 175.

A pixel electrode 190 is formed on the passivation layer 180. The pixel electrode 190 is physically and electrically connected to the output electrode 175 through the contact hole 185, and it is preferably made of a transparent conductor such as, but not limited to, ITO or IZO, or a reflective metal such as Al or a Ag alloy.

A partition 361, such as a bank layer, is formed on the passivation layer 180. The partition 361 encloses the pixel electrode 190 to define an opening on the pixel electrode 190 like a bank, and it is preferably made of an organic or inorganic insulating material.

An organic light emitting member 370 is formed on the pixel electrode 190, and it is confined within the opening enclosed by the partition 361.

The organic light emitting member 370, as shown in FIG. 4, has a multi-layered structure including an emitting layer EML and auxiliary layers for improving the efficiency of light emission of the emitting layer EML. The auxiliary layers include an electron transport layer ETL and a hole transport layer HTL flanking opposing sides of the emitting layer EML for improving the balance of electrons and holes and an electron injecting layer EIL and a hole injecting layer HIL disposed adjacent the electron transport layer ETL and the hole transport layer HTL, respectively, for improving the injection of electrons and holes. In an alternative embodiment, the auxiliary layers may be omitted.

A common electrode 270 that is supplied with a common voltage Vss is formed on the organic light emitting member 370 and the partition 361. The common electrode 270 is preferably made of a reflective metal such as, but not limited to, Ca, Ba, Al, and Ag or a transparent conductive material such as, but not limited to, ITO and IZO.

A combination of opaque pixel electrodes 190 and a transparent common electrode 270 is employed in a top emission type of OLED display that emits light toward the top of the display panel 300, and a combination of transparent pixel electrodes 190 and an opaque common electrode 270 is employed in a bottom emission type of OLED display that emits light toward the bottom of the display panel 300.

A pixel electrode 190, an organic light emitting member 370, and a common electrode 270 form an OLED LD illustrated in FIG. 2 having the pixel electrode 190 as an anode and the common electrode 270 as a cathode, or vice versa. The OLED LD uniquely emits light of one color among the main colors depending on the material of the light emitting member 370. An example of a set of the colors includes the three colors of red, green, and blue, and desired colors are displayed by a spatial sum of the three colors.

Referring to FIG. 1 again, the scanning driver 400 is connected to the scanning lines G₁-Gₙ and synthesizes a high voltage Von for turning on the switching transistors Qs and a low voltage Voff for turning off the switching transistors Qs to generate scanning signals, which are applied to the scanning lines G₁-Gₙ.

The data driver 500 is connected to the data lines D₁-Dₘ and applies data voltages to the data lines D₁-Dₘ.

The signal controller 600 controls the operation of the scanning driver 400 and the data driver 500, and compensates the input image data R, G, and B.

The scanning driver 400 or the data driver 500 may be implemented as at least one drive integrated circuit (“IC”) chip directly mounted on the display panel 300, or they may be mounted on a flexible printed circuit film (not shown) in a tape carrier package (“TCP”) type which is attached to the display panel 300. Alternatively, the scanning driver 400 or the data driver 500 may be integrated with the display panel 300. Also, they may be integrated into one chip.

The signal controller 600 is supplied with input image data R, G, and B and input control signals controlling the display thereof, such as a vertical synchronization signal Vsync, a horizontal synchronization signal Hsync, a main clock signal MCLK, and a data enable signal DE, from an external graphics controller (not shown).

After compensating the input image data R, G, and B on the basis of the input image data R, G, and B and the input control signals to generate output image data DAT and generating scanning control signals CONT1 and data control signals CONT2, the signal controller 600 transmits the scanning control signals CONT1 to the scanning driver 400, and the data control signals CONT2 and the output image data DAT to the data driver 500.

The scanning control signals CONT1 include a scanning start signal STV for instructing to start scanning a high voltage and at least one clock signal for controlling the output of the high voltage Von.

The data control signals CONT2 include a horizontal synchronization start signal STH for informing of start of data transmission for a row of pixels PX, a load signal LOAD for instructing to apply the data voltages to the data lines D₁-Dₘ, and a data clock signal HCLK.

In response to the data control signals CONT2 from the signal controller 600, the data driver 500 sequentially receives the image data DAT for a row of pixels, converts each image data DAT into a data voltage, and applies the data voltage to the corresponding data lines D₁-Dₘ.

The scanning driver 400 applies the scanning signals to the scanning lines G₁-Gₙ in response to the scanning control signals CONT1 from the signal controller 600, thereby turning on the switching transistors Qs connected the scanning lines G₁-Gₙ, and accordingly the data voltages applied to the data lines D₁-Dₘ are supplied to the control terminals of the driving transistors Qd through the turned-on switching transistors Qs.

The data voltages supplied to the driving transistors Qd are stored in the capacitors Cst and preserved even after the switching transistors Qs are turned off.

Each of the driving transistors Qd supplied with the data voltages is turned on and outputs current I_{LD} having a magnitude depending on the data voltages. Then, this current I_{LD} flows into the OLED LD from the output terminal of the driving transistor Qd, and the respective pixels PX display images.

After one horizontal period (or “1H” which is equal to one period of a horizontal synchronization signal Hsync and a data enable signal DE), the data driver 500 and the scanning driver 400 repeat the same operation for the next row of pixels PX. In this way, all scanning lines G₁-Gₙ are sequentially supplied with the scanning signals during a frame, thereby applying the data voltages to all pixels PX. The next frame starts after one frame is finished, and the same operation is repeated in the next frame.

Now, various examples of an OLED display according to exemplary embodiments of the present invention will be described.

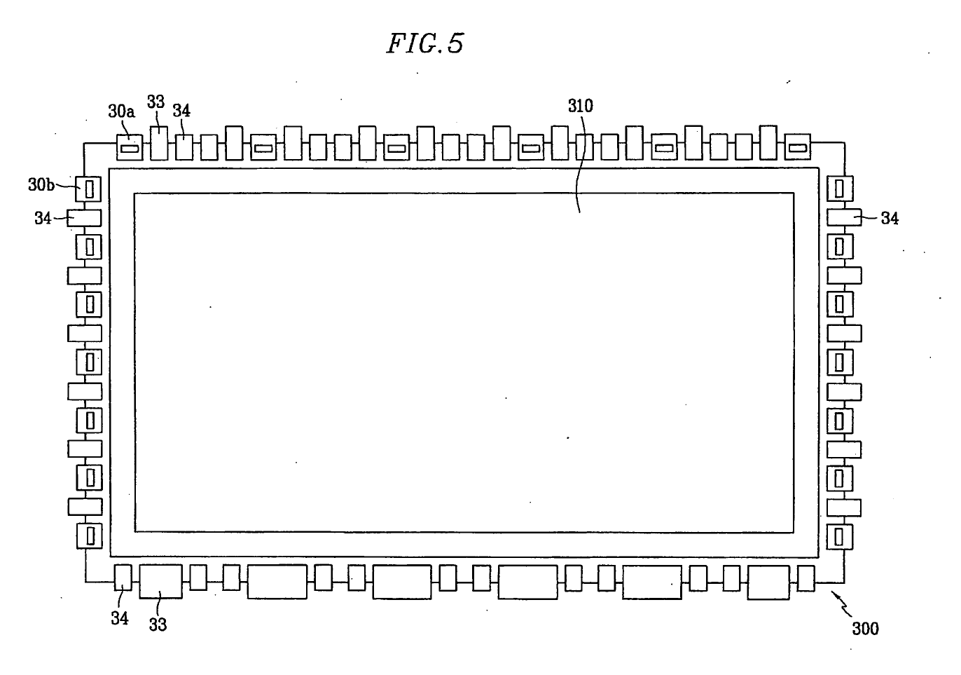

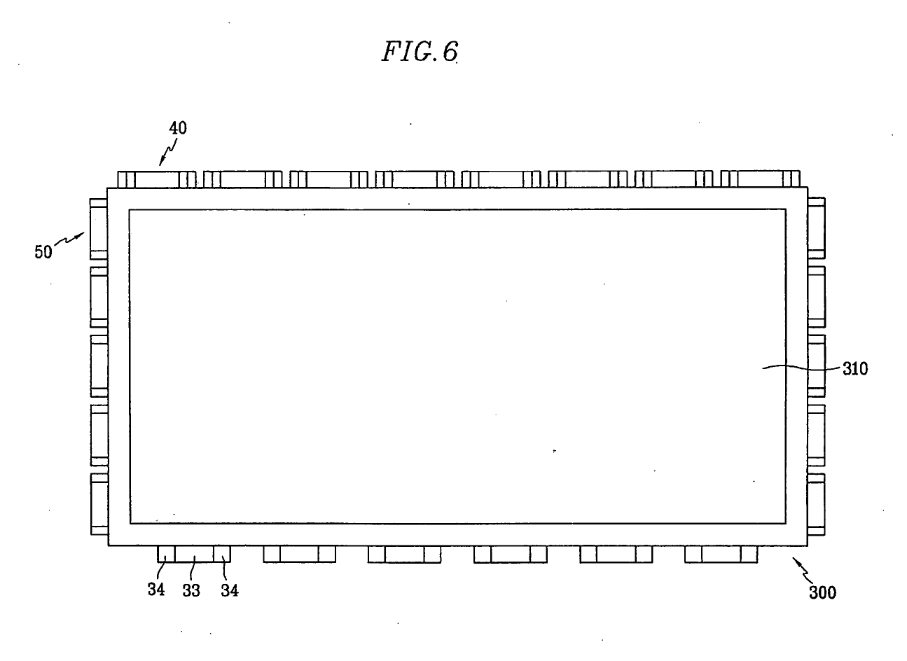

FIG. 5 and FIG. 6 are plan views of an exemplary OLED display according to various exemplary embodiments of the present invention.

Referring to FIG. 5 and FIG. 6, an OLED display includes an OLED display panel 300. The OLED display panel 300 includes a display region 310 provided with a plurality of pixels and substantially displays images. The peripheral region (edge area) outside of the display region 310 of the OLED display panel 300 is for attachment of various members for driving the OLED display panel 300.

Referring to FIG. 5, a plurality of data drive circuit packages 30a are attached to an upper peripheral region (or alternatively a lower peripheral region) of the OLED display panel 300, and a plurality of scanning drive circuit packages 30b are attached to at least one side peripheral region of the OLED display panel 300. Each of the data drive circuit packages 30a and the scanning drive circuit packages 30b includes a flexible printed circuit (“FPC”) film and a drive circuit chip mounted thereon that may be a tape carrier package (“TCP”) type or a chip on film (“COF”) type. Not being limited to the above, however, the circuits may be mounted directly on the display panel 300 or integrated with the display panel 300.

FPC films 33 and 34 are attached between a plurality of data drive circuit packages 30a , between the scanning drive circuit packages 30b , and to remaining edges of the OLED display panel 300, such as the lower peripheral region of the OLED display panel 300.

The drive circuit packages 30a and 30b and the FPC films 33 and 34 are also attached to a printed circuit board (“PCB”, not shown), the drive circuit packages 30a and 30b are supplied with image data and various control signals from the PCB and then apply data voltages and so forth to the OLED display panel 300, and the FPC films 33 and 34 transmit a drive voltage Vdd or a common voltage Vss supplied from the PCB to the OLED display panel 300. The drive voltage Vdd is transmitted substantially upward and downward in the OLED display panel 300, and the common voltage Vss may be transmitted upward and downward, or from side to side in the OLED display panel 300.

In FIG. 5, the data drive circuit packages 30a or the scanning drive circuit packages 30b, along with the FPC films 33 and 34, are not limited to the illustrated embodiments, and may be attached to other edges of the display panel 300. Also, though the scanning drive circuit packages 30b are illustrated as attached to both left and right peripheral regions of the OLED display panel 300, the scanning drive circuit packages 30b may alternatively be attached to only one side peripheral region along with the FPC films 33 and 34, and only the FPC films 33 and 34 may be attached to the other side peripheral region.

Referring to FIG. 6, a plurality of first drive packages 40 are successively attached to the top edge of the OLED display panel 300, and a plurality of second drive packages 50 are successively attached to the left and the right sides of the OLED display panel 300. Alternatively, the first drive packages 40 may be attached to the lower edge of the OLED display panel 300, and in yet another alternative embodiment, the second drive packages 50 may be attached to only one of the side edges of the OLED display panel 300.

The drive packages 40 and 50 apply data voltages or scanning voltages as well as transmit a common voltage Vss and/or a drive voltage Vdd to the OLED display panel 300. The first drive packages 40 attached to the upper peripheral region of the OLED display panel 300 mainly include data drive voltage circuits, and the second drive packages 50 attached to the side peripheral regions of the OLED display panel 300 mainly include scanning drive voltage circuits.

The plurality of FPC films 33 and 34 are attached to remaining edges of the OLED display panel 300, such as, in the illustrated embodiment, the lower peripheral region of the OLED display panel 300. One of the FPC films 33 and 34 may transmit a drive voltage Vdd, and the other a common voltage Vss. Not being limited to the above, however, the first drive packages 40 may be attached to the lower peripheral region of the OLED display panel 300 as necessary. Also, although the second drive packages 50 are attached to the right peripheral region, when necessary only the FPC films 33 and 34 may be attached thereto.

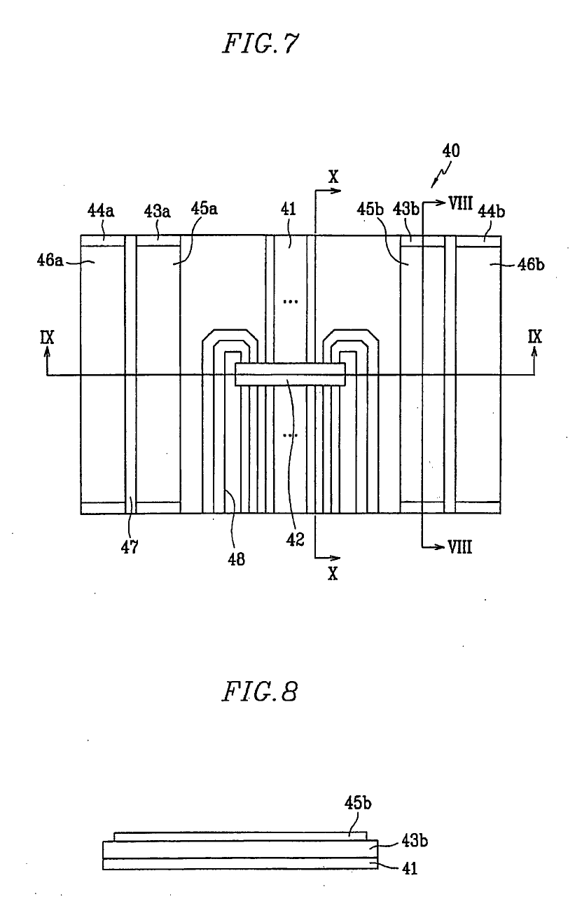

Now, the first and second drive packages 40 and 50 will be further described with reference to FIG. 7 to FIG. 13.

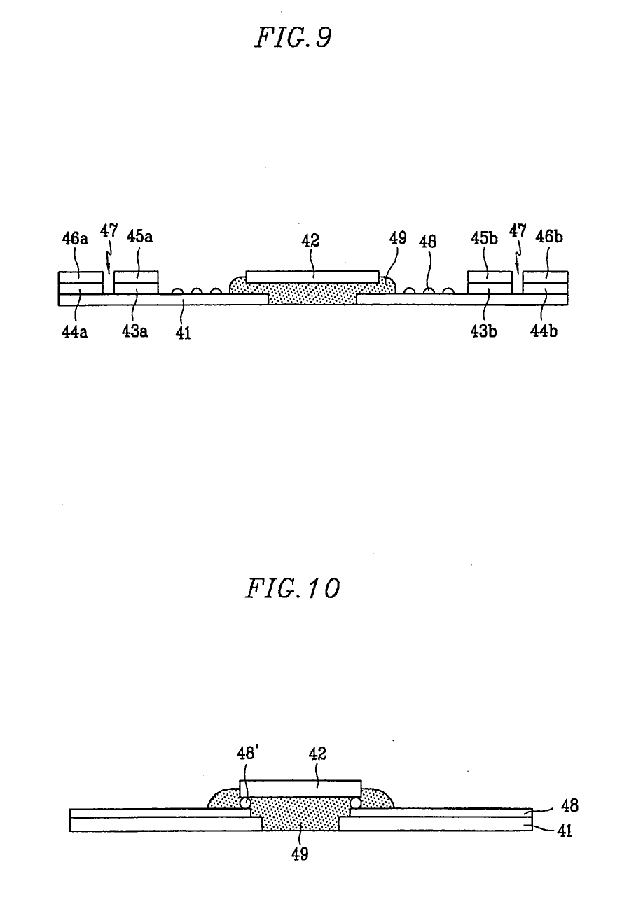

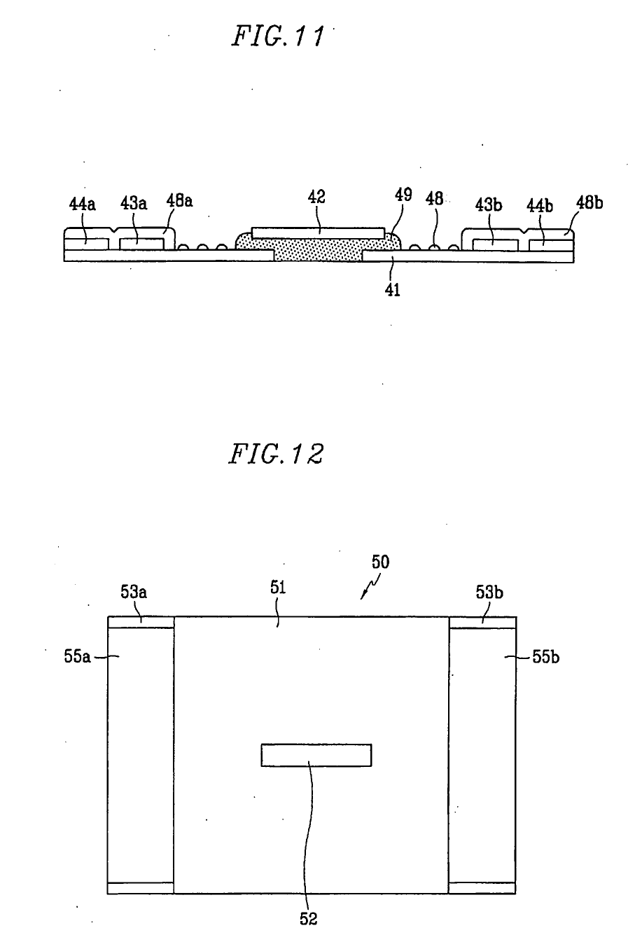

FIG. 7 is a plan view of a first drive package 40 according to an exemplary embodiment of the present invention, and FIG. 8, FIG. 9, and FIG. 10 are sectional views of the first drive package 40 shown in FIG. 7 taken along line VIII-VIII, line IX-IX, and line X-X, respectively. FIG. 11 is a sectional view of a first drive package 40 according to another exemplary embodiment of the present invention. FIG. 12 is a plan view of a second drive package 50 according to an exemplary embodiment of the present invention.

Referring to FIG. 7 to FIG. 10, a first drive package 40 includes a base film 41, metal wiring 48 formed on the base film 41, a drive circuit chip 42 mounted on the base film 41, and conductors 43a, 43b, 44a, and 44b formed on both side peripheral regions of the base film 41.

The base film 41 is a supporting body of the first drive package 40 and protects the conductors 43a, 43b, 44a, and 44b, the drive circuit chip 42, and the metal wiring 48 that are connected to the drive circuit chip 42, and so forth. The base film 41 has insulating properties and flexibility, and it may be made of a material such as, but not limited to, polyimide.

The drive circuit chip 42 is mounted on a central part of the base film 41. The drive circuit chip 42 may be secured relative to the base film 41 using adhesive 49. The drive circuit chip 42 is a data drive IC chip that applies data voltages to the OLED display panel 300.

The metal wiring 48 is connected to the drive circuit chip 42 via connecting members 48′ formed as bumps, for example, on the base film 41, from the drive circuit chip 42 towards the input terminal and the output terminal of the base film 41. That is, the metal wiring 48 may carry signals, such as data voltages, from a PCB connected to the input terminal located on a first edge of the first drive package 40 to the drive circuit chip 42, and then the metal wiring 48 may carry the data voltages from the drive circuit chip 42 to the output terminal located on a second edge, opposite the first edge, of the first drive package 40. In FIG. 7, although the metal wiring 48 is illustrated as formed on the base film 41, the metal wiring 48 may alternatively be formed under the base film 41.

The two pairs of conductors 43a, 43b, 44a, and 44b are formed on both side peripheral regions of the base film 41, and extend from the first edge of the first drive package 40 at the input terminal to the second edge of the first drive package 40 at the output terminal. That is, the first drive package 40 includes third and fourth edges that connect the first edge to the second edge of the first drive package 40. A first pair of the conductors 43a and 44a are formed adjacent the third edge, on one side of the drive circuit chip 42, and the second pair of conductors 43b and 44b are formed adjacent the fourth edge, on an opposite side of the drive circuit chip 42. In particular, the conductor 43a is disposed between the conductor 44a and the drive circuit chip 42, and the conductor 43b is disposed between the conductor 44b and the drive circuit chip 42. The pairs of conductors 43a, 43b, 44a, and 44b are made of a metal having good conductivity such as, but not limited to, copper (Cu). Each of the conductors 43a, 43b, 44a, and 44b may be band-shaped having a substantially rectangular cross-section, and having a greater cross-sectional area than each of the wires in the metal wiring 48. By “band-shaped”, it is meant that each of the conductors 43a, 43b, 44a, and 44b may have the shape of a thin flat strip, with a width substantially greater than a thickness thereof, and a length extending across the base film 41 from the first edge to the second edge. Each of the conductors 43a, 43b, 44a, and 44b is disposed with a predetermined gap 47 between each other to protect against short circuits between adjacent conductors 43a, 43b, 44a, and 44b. In particular, a gap 47 is provided between conductors 43a and 44a, and a gap 47 is provided between conductors 43b and 44b. Portions of the insulating base film 41 are exposed in the gaps 47. Alternatively, insulating members (not shown) may be formed between the conductors 43a, 43b, 44a, and 44b thus filling the gaps 47 between the conductors 43a, 43b, 44a, and 44b. Also, insulating members (not shown) may be formed between the conductors 43a and 43b and the metal wiring 48 to protect against short circuits between the conductors 43a and 43b and the metal wiring 48.

The conductors 43a, 43b, 44a, and 44b transmit a drive voltage Vdd or a common voltage Vss from a PCB (not shown) at the input terminal of the first drive package 40 to the OLED display panel 300 at the output terminal of the first drive package 40. One pair of the two pairs of conductors 43a, 43b, 44a, and 44b may transmit a common voltage Vss and the other pair a drive voltage Vdd.

Protective films 45a, 45b, 46a, and 46b are formed on the conductors 43a, 43b, 44a, and 44b, respectively. The protective films 45a, 45b, 46a, and 46b are preferably made of an insulating material. Here, the protective films 45a, 45b, 46a, and 46b are formed by exposing both ends in the length direction of the conductors 43a, 43b, 44a, and 44b, therefore, the protective films 45a, 45b, 46a, and 46b are formed to be shorter than the conductors 43a, 43b, 44a, and 44b. Thus, first ends of the exposed portions of the conductors 43a, 43b, 44a, and 44b adjacent the first edge of the first drive package 40 are used as pads to connect the input terminal of the drive package 40 and the PCB, and the other ends of the exposed portions thereof adjacent the second edge of the first drive package are used as pads to connect the output terminal of the drive package 40 and the OLED display panel 300. As described above, a common voltage Vss and a drive voltage Vdd can be supplied to the OLED display panel 300 via the conductors 43a, 43b, 44a, and 44b, and data voltages can be supplied to the OLED display panel 300 via the metal wiring 48, and the manufacturing process of the OLED display panel 300 is simplified by using one drive package 40.

Referring to FIG. 11, a drive package 40 according to another exemplary embodiment of the present invention includes two protective films 48a and 48b, where protective film 48a covers a first pair of conductors 43a and 44a, and protective film 48b covers a second pair of conductors 43b and 44b, respectively. That is, such protective films 48a and 48b cover the adjacent conductors entirely instead of separately providing protective films for individual conductors 43a, 43b, 44a, and 44b as shown in FIGS. 7 to 9. Therefore, since the protective films 48a and 48b made of an insulating material fill in the gap 47 between the adjacent pair of conductors 43a and 44a, and 44a and 44b, short circuits between the conductors 43a and 44a, and 44a and 44b can be more effectively prevented.

Referring to FIG. 12, a second drive package 50 according to an exemplary embodiment of the present invention includes a base film 51, a drive circuit chip 52 mounted on the base film 51, and conductors 53a and 53b formed on both side peripheral regions of the base film 51. The conductors 53a and 53b both extend from a first edge of the second drive package 50, corresponding to an input terminal, to a second edge of the second drive package 50, corresponding to an output terminal. The second drive package 50 may further include third and fourth edges that connect the first edge to the second edge. The conductor 53a may be positioned adjacent the third edge, and the conductor 53b may be positioned adjacent the fourth edge, where the drive circuit chip 52 is disposed between the conductor 53a and the conductor 53b. Unlike the first drive package 40 illustrated in FIG. 7, the second drive package 50 includes a single pair of conductors 53a and 53b. Metal wiring (not shown) may extend from the first edge to the drive circuit chip 52 and from the drive circuit chip 52 to the second edge. The metal wiring may transmit scanning signals from the input terminal to the output terminal of the second drive package 50. An insulating member (not shown) may be provided between each of the conductors 53a and 53b and the metal wiring. The conductors 53a and 53b may be covered by protective films 55a and 55b, respectively, which expose end portions of the conductors 53a and 53b adjacent the first and second edges of the second drive package 50. End portions of the conductors 53a and 53b adjacent the first edge may be used as pads to connect the input terminal of the second drive package 50 to the PCB and end portions of the conductors 53a and 53b adjacent the second edge may be used as pads to connect the output terminal of the second drive package to the OLED display panel 300. Each of the conductors 53a, 53b may be band-shaped having a substantially rectangular cross-section, and having a greater cross-sectional area than each of the wires in the metal wiring. The conductors 53a and 53b supply a common voltage Vss to the OLED display panel 300. Not being limited to this, however, the conductors 53a and 53b may alternatively supply a drive voltage Vdd as necessary, and this kind of second drive package 50, while illustrated in FIG. 6 as attached to left and right edges of the OLED display panel 300, may instead be attached to the upper (or lower) peripheral region of the OLED display panel 300 instead of the first drive package 40.

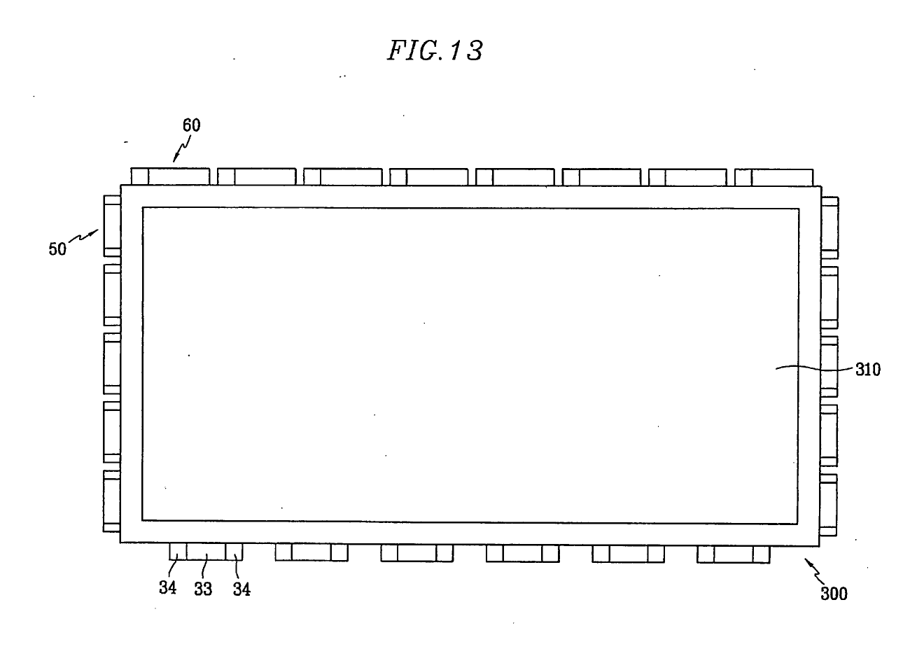

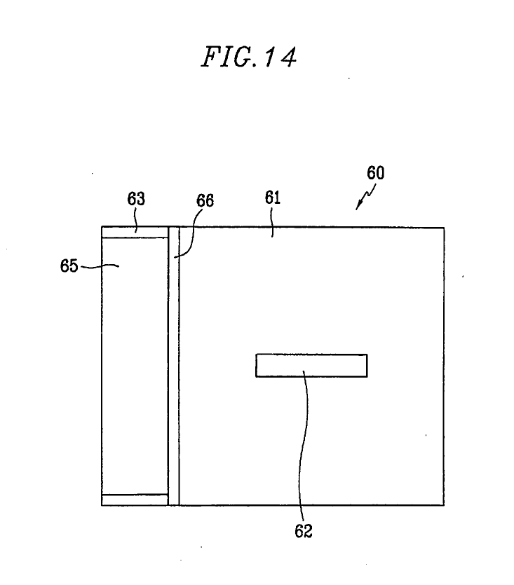

Now, an exemplary OLED display panel according to another exemplary embodiment of the present invention will be described with reference to FIG. 13 and FIG. 14.

FIG. 13 is a plan view of an exemplary OLED display panel according to another exemplary embodiment of the present invention, and FIG. 14 is a plan view of an exemplary drive package according to another exemplary embodiment of the present invention.

Referring to FIG. 13, third drive packages 60 are successively attached to an upper edge (or alternatively a lower edge) of an OLED display panel 300. Also in this illustrated embodiment, a plurality of second drive packages 50 are provided on left and right edges of the OLED display panel 300, and FPC films 33, 34 are provided on a lower edge of the OLED display panel 300. It should be understood, however, that an arrangement of the second and third drive packages 50, 60 and the FPC films 33, 34 with respect to edges of the OLED display panel 300 may be changed in alternative embodiments.

Referring to FIG. 14, the third drive package 60 includes a drive circuit chip 62 mounted on a base film 61, and a conductor 63 formed on one side peripheral region, which is covered with a protective film 65. The conductor 63 extends from a first edge of the third drive package 60, forming an input terminal, to a second edge of the third drive package 60, forming an output terminal. The third drive package 60 may further include third and fourth edges connecting the first edge to the second edge. The conductor 63 may be positioned adjacent either the third edge or the fourth edge of the third drive package 60. The protective film 65 may cover the conductor 63 so as to expose end portions of the conductor 63 adjacent the first and second edges of the third drive package 60. Metal wiring (not shown) may be provided to connect the input terminal to the drive circuit chip 62 and to connect the drive circuit chip 62 to the output terminal. The conductor 63 may be band-shaped having a substantially rectangular cross-section, and having a greater cross-sectional area than each of the wires in the metal wiring. Also, an insulating member 66 is located between the conductor 63 and the metal wiring (not shown) to protect against short circuits. The conductor 63 of the drive package 60 illustrated in FIG. 14, unlike the drive packages 40 and 50 illustrated in FIG. 7 and FIG. 12, is formed on only one side of the drive package 60. The conductor 63 may transmit a common voltage Vss or a drive voltage Vdd to the OLED display panel 300 via the output terminal of the third drive package 60. Third drive packages 60 in which the conductor 63 may transmit a common voltage Vss, and third drive packages 60 in which the conductor may transmit a drive voltage Vdd may be attached alternately to the upper edge (or lower edge) of the OLED display panel 300. Thereby, a common voltage Vss and a drive voltage Vdd as well as data voltages transmitted by the metal wiring can be supplied to the OLED display panel 300 more effectively in a limited area.

Now, an exemplary manufacturing method of the drive packages 40, 50, and 60 according to exemplary embodiments of the present invention will be described.

First, metal wiring is formed on or under base films 41, 51, and 61, respectively, including a hole formed in a central region thereof. The metal wiring is formed in substantially one direction of length of the base films 41, 51, and 61, and is connected respectively to two sides facing each other of the base films 41, 51, and 61 near the holes. Then, drive circuit chips 42, 52, and 62 are mounted on the holes of the base films 41, 51, and 61 so as to be connected to the metal wiring. The base films 41, 51, and 61 may serve as first base films in their respective drive packages.

Then, conductive layers 43a, 43b, 44a, 44b, 53a, 53b , and 63 are formed on other base films, such as second base films and third base films. Next, protective films 45a, 45b, 46a, 46b, 55a, 55b, and 65 are formed on the conductive layers 43a, 43b, 44a, 44b, 53a, 53b, and 63 so that opposite ends of the conductive layers 43a, 43b, 44a, 44b, 53a, 53b, and 63 in the length direction thereof are exposed.

Then, the base films, such as the second base film as in the case of the third drive package 60, or the second and third base films as in the case of the first and second drive packages 40 and 50, on which the conductive layers 43a, 43b, 44a, 44b, 53a, 53b, and 63 are formed and the first base films on which the drive circuit chips 42, 52, and 62 are formed are attached to each other.

Here, two conductive layers, as shown in FIG. 7, may be provided on each side respectively with respect to the drive circuit chip 42, or one conductive layer, as shown in FIG. 12, may be provided on each side with respect to the drive circuit chip 52, or only one conductive layer, as shown in FIG. 14, may be provided on only one side.

As described above, according to exemplary embodiments of the present invention, much more current can be supplied effectively in the limited area of the OLED display panel, and processes of manufacturing can be progressed more simply with a lower cost.

Although exemplary embodiments of the present invention have been described hereinabove, it should be clearly understood that many variations and/or modifications of the basic inventive concepts herein taught which may appear to those skilled in the present art will still fall within the spirit and scope of the present invention, as defined in the appended claims.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A drive package for an organic light emitting diode display, the drive package comprising:
a base film including a central region and a peripheral region;
a drive circuit chip mounted on the central region of the base film;
a plurality of conductors formed on at least one portion of the peripheral region of the base film; and
at least one protective film formed on the conductors, the at least one protective film exposing both ends of the conductors in a lengthwise direction.

2. The drive package of claim 1, wherein the conductors comprise one pair of conductors formed to face each other on opposing sides of the base film.

3. The drive package of claim 2, wherein the drive circuit chip is disposed between the conductors in the pair of conductors.

4. The drive package of claim 1, wherein the conductors comprise a first pair of conductors formed on a first side of the base film and a second pair of conductors formed on a second side of the base film, a first gap disposed between the first pair of conductors and a second gap disposed between the second pair of conductors.

5. The drive package of claim 1, wherein the base film comprises polyimide.

6. The drive package of claim 1, wherein the conductors comprise copper.

7. The drive package of claim 1, wherein each of the plurality of conductors is a thin flat strip extending from an input terminal to an output terminal of the drive package, and each of the plurality of conductors has a width greater than a thickness thereof.

8. The drive package of claim 1, wherein each of the plurality of conductors is substantially rectangular-shaped.

9. The drive package of claim 1, wherein the base film comprises a first base film supporting the drive circuit chip and a second base film supporting at least one of the plurality of conductors, the first base film connected to the second base film.

10. The drive package of claim 9, wherein the base film further comprises a third base film supporting at least one of the plurality of conductors, the third base film connected to the first base film.

11. The drive package of claim 1, further comprising metal wiring extending from an input terminal to the drive circuit chip and from the drive circuit chip to an output terminal, wherein a cross-sectional area of each of the conductors is substantially greater than a cross-sectional area of each wire in the metal wiring.

12. An organic light emitting diode display comprising:
a substrate,
a display region formed on the substrate, and
a plurality of first drive packages successively attached to an upper or lower peripheral region of the substrate outside of the display region of the substrate,
wherein each of the first drive packages comprises:
a base film including a central region and a peripheral region;
a first drive circuit chip mounted on the central region of the base film;
a plurality of conductors formed on at least one portion of the peripheral region of the base film; and
at least one protective film formed on the conductors, the at least one protective film exposing both ends of the conductors in a lengthwise direction.

13. The organic light emitting diode display of claim 12, wherein the conductors comprise one pair of conductors formed to face each other on opposing sides of the base film.

14. The organic light emitting diode display of claim 13, wherein the first drive circuit chip is disposed between the conductors in the pair of conductors.

15. The organic light emitting diode display of claim 12, wherein the conductors comprise a first pair of conductors formed on a first side of the base film, and a second pair of conductors formed on a second side of the base film, a first gap disposed between the first pair of conductors and a second gap disposed between the second pair of conductors.

16. The organic light emitting diode display of claim 12, wherein the conductors transmit a common voltage or a drive voltage.

17. The organic light emitting diode display of claim 12, wherein the drive circuit chip comprises a data drive integrated circuit.

18. The organic light emitting diode display of claim 12, wherein each of the plurality of conductors is a thin flat strip extending from an input terminal to an output terminal of each of the first drive packages, and each of the plurality of conductors has a width greater than a thickness thereof.

19. The organic light emitting diode display of claim 12, wherein the base film in each of the first drive packages comprises a first base film supporting the first drive circuit chip and a second base film supporting at least one of the plurality of conductors, the first base film connected to the second base film.

20. The organic light emitting diode display of claim 12, further comprising a plurality of second drive packages successively attached to a left or right peripheral region of the substrate outside of the display region of the substrate,
wherein each of the second drive packages comprises:
a base film including a central region and a peripheral region;
a drive circuit chip mounted on the central region of the base film of the second drive packages;
conductors formed on at least one portion of the peripheral region of the base film of the second drive packages; and
at least one protective film formed on the conductors of the second drive packages, the at least one protective film of the second drive packages exposing both ends of the conductors of the second drive packages in a lengthwise direction.

21. The organic light emitting diode display of claim 20, wherein the conductors of the second drive packages transmit a common voltage.

22. The organic light emitting diode display of claim 20, wherein the drive circuit chip of the second drive packages comprises a scanning drive integrated circuit.

23. The organic light emitting diode display of claim 20, wherein the conductors of the second drive packages comprise one pair of conductors formed to face each other on opposing sides of the base film.

24. A manufacturing method of a drive package for an organic light emitting diode display, the method comprising:
forming metal wiring on a first base film;
mounting a drive circuit chip connected to the metal wiring on the first base film;
forming at least one conductor on a second base film;
forming at least one protective film on the at least one conductor, the at least one protective film exposing both ends in a lengthwise direction of the at least one conductor; and
attaching the first base film and the second base film to each other.

25. The method of claim 24, wherein the at least one conductor comprises one pair of conductors separated from each other.

26. The method of claim 24, wherein forming at least one conductor on the second base film comprises forming each of the at least one conductor in a shape of a thin flat strip from an input terminal to an output terminal of the drive package, and having a width substantially greater than a thickness thereof.

27. The method of claim 24, wherein forming at least one conductor on the second base film comprises forming each of the at least one conductor with a cross-sectional area substantially greater than a cross-sectional area of each wire in the metal wiring.

28. The method of claim 24, further comprising:
forming at least one conductor on a third base film;
forming at least one protective film on the at least one conductor on the third base film, the protective film on the third base film exposing both ends in a lengthwise direction of the at least one conductor on the third base film; and
attaching the third base film and the first base film to each other.

29. The method of claim 28, wherein the at least one conductor on the third base film comprises one pair of conductors separated from each other.

30. A drive film for a drive package of an organic light emitting diode display, the drive film comprising:
a first base film having a hole in a central region, the hole sized to receive a drive circuit chip, the first base film having a first edge corresponding to an input terminal of the drive package, a second edge corresponding to an output terminal of the drive package, the second edge opposite the first edge, a third edge, and a fourth edge opposite the third edge; and,
a second base film attached to the third edge of the first base film during manufacture of the drive package.

31. The drive film of claim 30, further comprising a third base film, wherein the third base film is attached to the fourth edge of the first base film during manufacture of the drive package.
